(19) United States
(12) Patent Application Publication
(10) Pub. No.: US 2013/0170122 A1
(43) Pub. Date: Jul. 4, 2013

(54) ELECTRONIC APPARATUS AND HINGE STRUCTURE THEREOF

(71) Applicant: PEGATRON CORPORATION, Taipei City (TW)

(72) Inventors: Wei-Chih LAI, Taipei City (TW); Kuang-Jui CHENG, Taipei City (TW); Yung-Sheng LEE, Taipei City (TW); Chien-Feng MA, Taipei City (TW); Tien-Wen LIN, Taipei City (TW)

(73) Assignee: PEGATRON CORPORATION, Taipei City (TW)

(21) Appl. No.: 13/724,607

(22) Filed: Dec. 21, 2012

(30) Foreign Application Priority Data
Dec. 30, 2011 (TW) 100149964

(51) Int. Cl. G06F 1/16; H05K 5/02

(52) U.S. Cl. CPC G06F 1/16; H05K 5/0226
USPC 361/679.6; 361/679.01; 16/370

(57) ABSTRACT

An electronic apparatus includes a first casing, a second casing and a hinge structure. The hinge structure is pivotally connected to the first and second casings, and has a base, a rotating base, a first connecting element and a second connecting element. The base is disposed on the first casing. The rotating base is disposed on the second casing. Two ends of the first connecting element are pivotally connected to the base and the rotating base, respectively, and two ends of the second connecting element are also pivotally connected to the base and the rotating base, respectively. The rotating base rotates with respect to the base between a first position and a second position through the first and second connecting elements. When the first connecting element contacts the second connecting element, the rotating base is located at the second position.

### CROSS REFERENCE TO RELATED APPLICATIONS

This Non-provisional application claims priority under 35 U.S.C. §119(a) on Patent Application No(s). 100149964 filed in Taiwan, Republic of China on Dec. 30, 2011, the entire contents of which are hereby incorporated by reference.

### BACKGROUND

1. Technology Field

The disclosure relates to an electronic apparatus and a hinge structure thereof.

2. Related Art

Many electronic apparatuses have the foldable design to reduce their size, and the folded electronic apparatus is more convenient in storage. In a foldable electronic apparatus, a hinge structure is usually configured to connect separate parts so that the separate parts can be rotated with respect to each other.

FIG. 1 is a schematic diagram showing a conventional electronic apparatus 1. A hinge structure 2 connects the upper casing 11 to the lower casing 12 of the electronic apparatus 1, so that the upper casing 11 and the lower casing 12 can be relatively rotated to open or close the electronic apparatus 1.

However, since the hinge structure 2 is a single-axis structure, it is exposed out of the lower casing 12 of the electronic apparatus 1. In other words, the lower casing 12 must be cut one area off for configuring the hinge structure 2. This not only weakens the structural strength of the lower casing 12, but also deteriorates the aesthetic appearance of the electronic apparatus 1.

### SUMMARY OF THE INVENTION

In view of the foregoing, an objective of the invention is to provide an electronic apparatus and a hinge structure thereof, wherein the shape and appearance of the casings do not need to be changed for configuring the hinge structure.

To achieve the above objective, the embodiment of the present invention discloses a hinge structure for pivotally connecting a first casing to a second casing capable of being open or closed with respect to the first casing. The hinge structure includes a base, a rotating base, a first connecting element and a second connecting element. The base is disposed at the first casing, and the rotating base is disposed at the second casing. The first connecting element has a retaining trough, and two ends of the first connecting element are pivotally connected to the base and the rotating base, respectively. Two ends of the second connecting element are pivotally connected to the base and the rotating base, respectively, and the shape of a part of the second connecting element is matched with the retaining trough. A distance between positions on the rotating base where the first connecting element and the second connecting element are pivotally connected is smaller than a distance between positions on the base where the first connecting element and the second connecting element are pivotally connected. The rotating base rotates between a first position and a second position with respect to the base through the first connecting element and the second connecting element. When the second casing is closed with respect to the first casing, the rotating base is at the first position; otherwise, when the second casing is open with respect to the first casing, the rotating base is at the second position.

To achieve the above objective, the present invention further discloses an electronic apparatus, which comprises a first casing, a second casing, and a hinge structure. The second casing is capable of being open and closed with respect to the first casing. The hinge structure pivotally connects the first casing to the second casing, and includes a base, a rotating base, a first connecting element, and a second connecting element. The base is disposed at the first casing, and the rotating base is disposed at the second casing. The first connecting element has a retaining trough, and two ends of the first connecting element are pivotally connected to the base and the rotating base, respectively. Two ends of the second connecting element are pivotally connected to the base and the rotating base, respectively, the shape of a part of the second connecting element is matched with the retaining trough A distance between positions on the rotating base where the first connecting element and the second connecting element are pivotally connected is smaller than a distance between positions on the base where the first connecting element and the second connecting element are pivotally connected. The rotating base rotates between a first position and a second position with respect to the base through the first connecting element and the second connecting element. When the second casing is closed with respect to the first casing, the rotating base is at the first position; otherwise, when the second casing is open with respect to the first casing, the rotating base is at the second position.

In one embodiment, when the rotating base is at the second position, a part of the second connecting element is inserted into the retaining trough.

In one embodiment, the rotating base has a supporting surface, and an included angle between a normal line of the supporting surface at the first position and the normal line of the supporting surface at the second position ranges from 80 degrees to 100 degrees.

In one embodiment, the first connecting element has a plurality of first sub-connecting elements, and the second connecting element has a plurality of second sub-connecting element.

In one embodiment, the electronic apparatus further comprises an elastic element, and two ends of the elastic element are connected to the first casing and the second casing, respectively.

As mentioned above, the electronic apparatus and the hinge structure thereof of the invention uses a first connecting element and a second connecting element to pivotally connect a base to a rotating base. The base is disposed at the first casing of the electronic apparatus, and the rotating base is disposed at the second casing of the electronic apparatus. Since the hinge structure of the present invention forms a structure that the rotating base is capable of rotating with respect to the base, and uses the second connecting element to abut against the first connecting element to realize the position-limiting function, the hinge structure can be assembled without changing the shape and appearance of the first casing or the second casing. Therefore, the aesthetic appearance of the electronic apparatus can be improved and the structure of the casings can be strengthened.

### BRIEF DESCRIPTION OF THE DRAWINGS

The invention will become more fully understood from the detailed description and accompanying drawings, which are given for illustration only, and thus are not limitative of the present invention, and wherein:

FIG. 1 is a schematic diagram showing an electronic apparatus in the prior art;

FIG. 2 is a schematic diagram showing the electronic apparatus according to a preferred embodiment of the invention;

FIG. 3 is a schematic diagram showing the hinge structure according to the preferred embodiment of the invention;

FIGS. 4A to 4C are side views showing the operations of the first casing and the second casing of the electronic apparatus according to the preferred embodiment of the invention;

FIG. 5 is a schematic diagram showing a variation of the hinge structure according to the preferred embodiment of the invention; and

FIG. 6 is a schematic diagram showing a variation of the electronic apparatus according to a preferred embodiment of the invention.

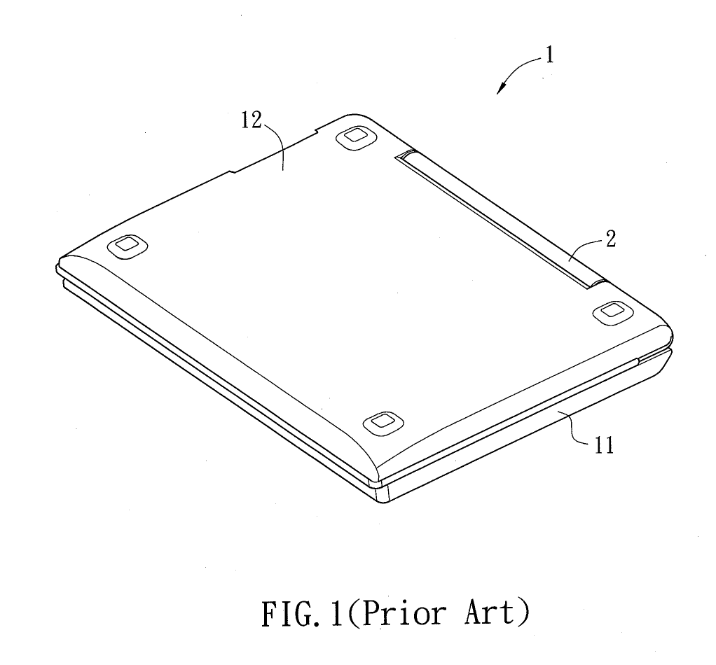

### DETAILED DESCRIPTION OF THE INVENTION

The present invention will be apparent from the following detailed description, which proceeds with reference to the accompanying drawings, wherein the same references relate to the same elements.

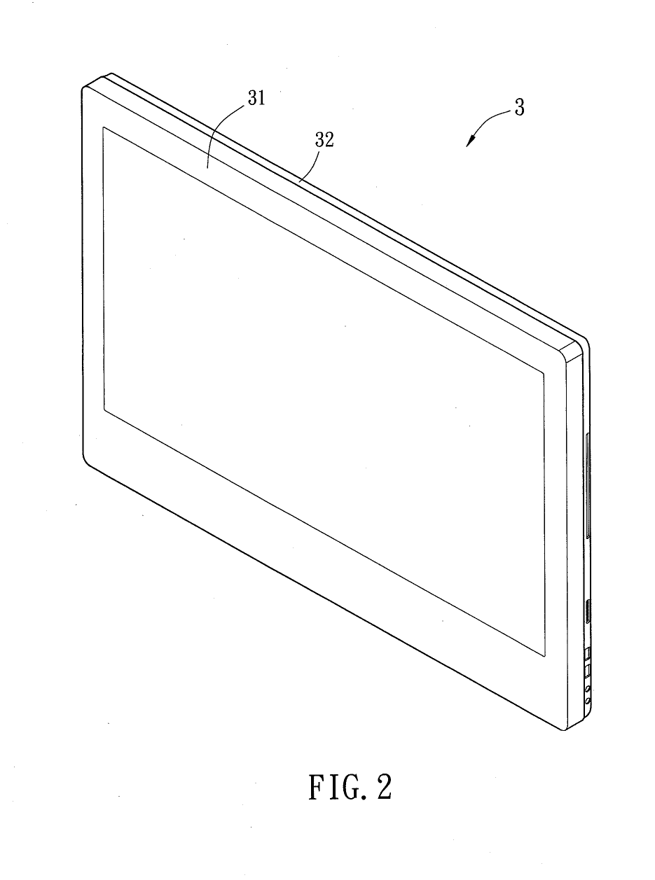

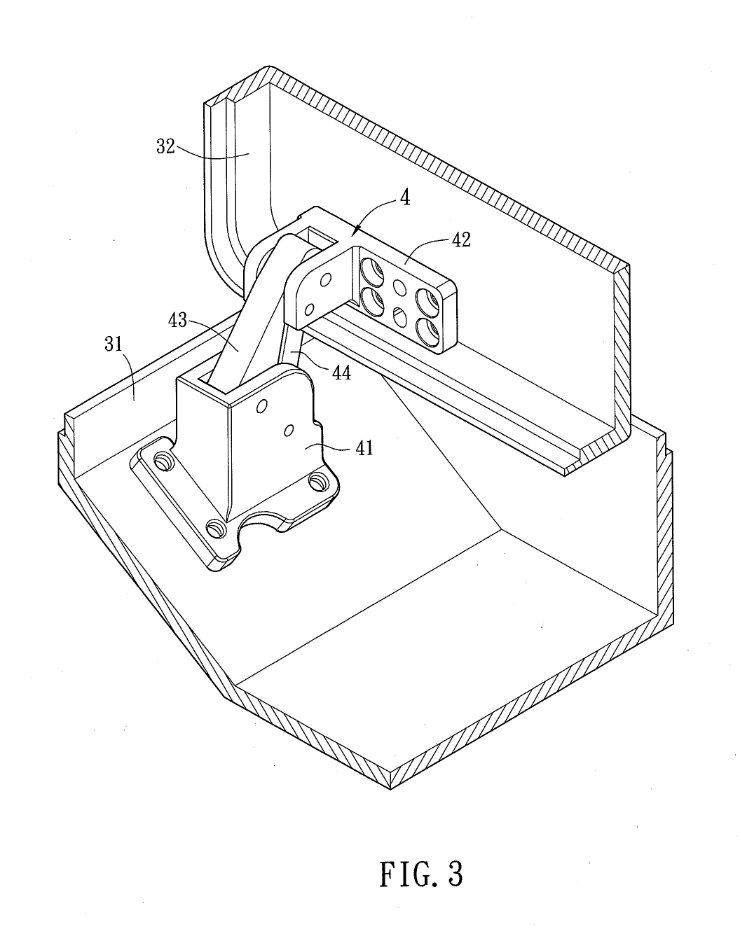

FIG. 2 is a schematic diagram showing the electronic apparatus 3 according to a preferred embodiment of the invention, and FIG. 3 is a schematic diagram showing a hinge structure 4 according to the preferred embodiment of the invention. It should be noted that in FIG. 3, the first casing 31 is open with respect to the second casing 32 for a more clarified description. Referring to FIG. 2 and FIG. 3, the electronic apparatus 3 includes a first casing 31, a second casing 32 and a hinge structure 4. The electronic apparatus may be, for example, an all-in-one desktop computer, a notebook computer or other foldable electronic apparatuses. In the present embodiment, the electronic apparatus 3 is an all-in-one desktop computer for exemplary purpose without limiting sense.

As shown in FIG. 3, the hinge structure 4 is pivotally connected to the first casing 31 and the second casing 32 capable of being open and closed with respect to each other, and includes a base 41, a rotating base 42, a first connecting element 43 and a second connecting element 44. The base 41 is disposed at the first casing 31, the rotating base 42 is disposed at the second casing 32, and the two ends of the first connecting element 43 and the second connecting element 44 are pivotally connected to the base 41 and the rotating base 42, respectively. It should be noted that in the present embodiment, the first casing 31 may be, for example, a front casing of the all-in-one desktop computer having a display panel, and the second casing 32 may be, for example, the rear casing of the all-in-one desktop computer. However, they are not in a limited sense. Based on the requirements, the first casing 31 connected to the base 41 may be the rear casing, and the second casing 32 connected to the rotating base 42 may be the front casing. With the base 41 always being connected to the first casing 31 and the rotating base 42 connected to the second casing 32, other different corresponding relationship may be possible in view of different electronic apparatus.

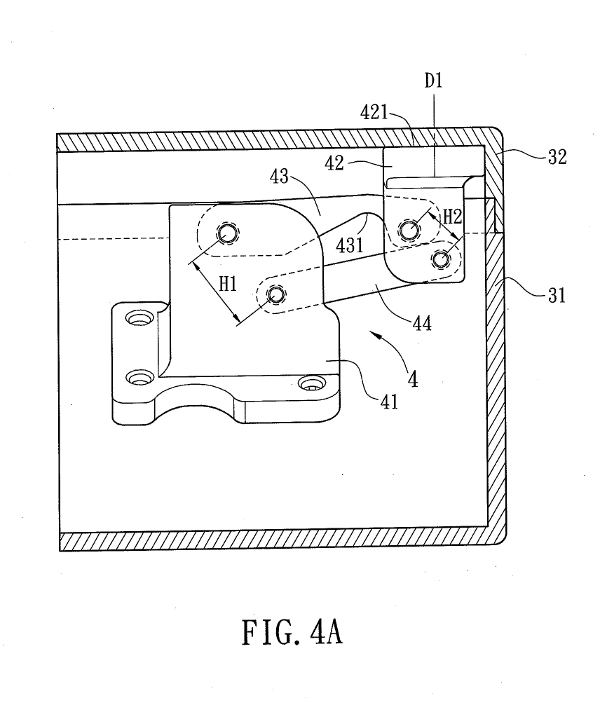

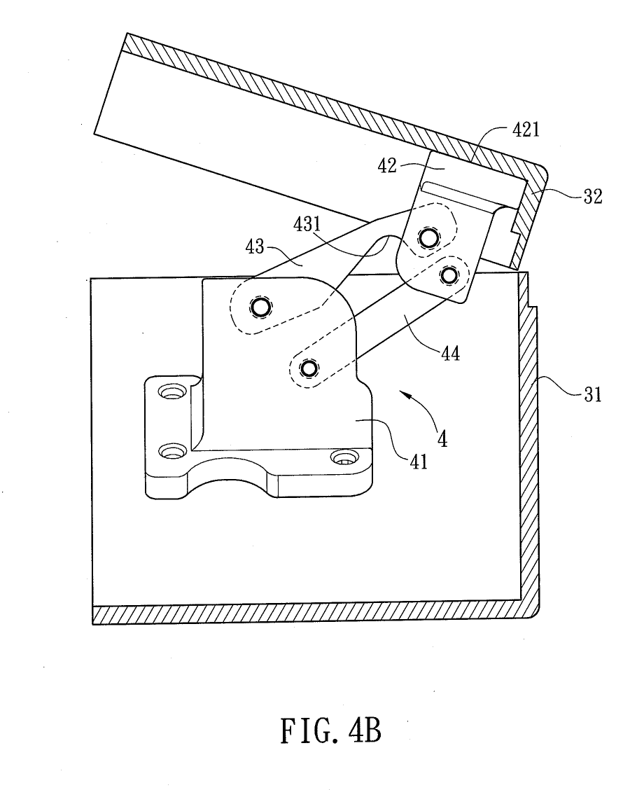

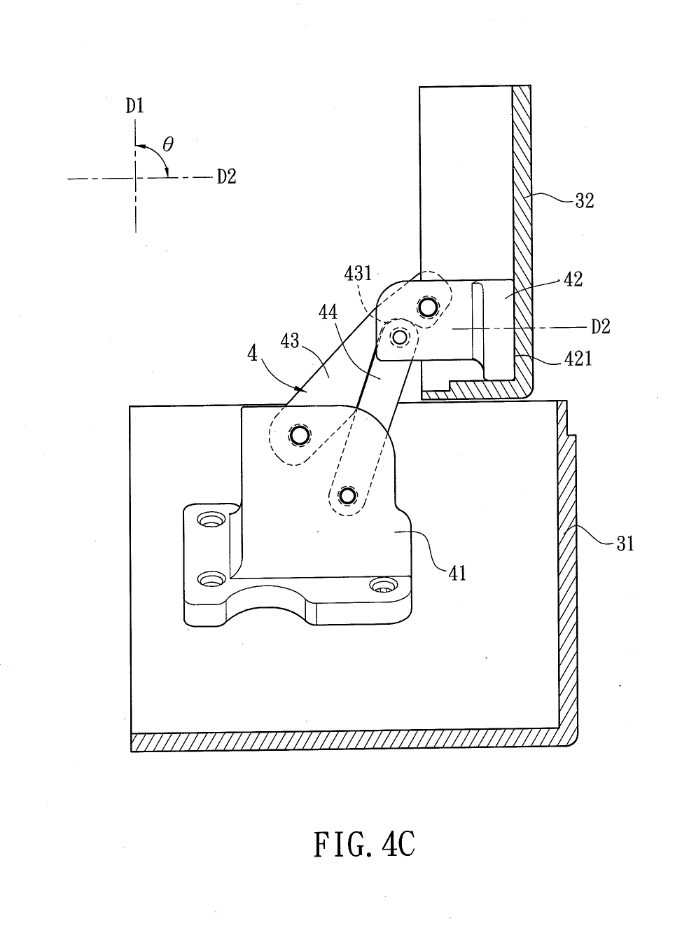

FIGS. 4A to 4C are side views showing the operations of the first casing 31 and the second casing 32 of the electronic apparatus 3 according to the preferred embodiment of the invention. Subsequently, please refer to FIGS. 4A to 4C with which the operations of the hinge structure 4 will be explained.

As shown in FIG. 4A, the rotating based 42 is located at a first position, and the second casing 32 is in a closed state with respect to the first casing 31. The distance H2 between the positions on the rotating base 42 where the first connecting element 43 and the second connecting element 44 are pivotally connected is smaller than the distance H1 between the positions on the base 41 where the first connecting element 43 and the second connecting element 44 are pivotally connected. Then, as shown in FIG. 4B, when the user applies force upwardly to open the second casing 32, the rotating base 42 rotates with respect to the base 41 via the first connecting element 43 and the second connecting element 44, and makes the second casing 32 connected to the rotating base 42 rotate upwardly to be opened with respect to the first casing 31.

When the user keeps applying force, as shown in FIG. 4C, the second connecting element 44 abuts against and contacts with the first connecting element 43, which makes the rotating base 42 stop at a second position, and at the same time the second casing 32 is in an open state with respect to the first casing 31. Therefore, the rotating base 42 of the hinge structure 4 of the present embodiment can be rotated between the first position (as shown in FIG. 4A) and the second position (as shown in FIG. 4C) with respect to the base 41 via the first connecting element 43 and the second connecting element 44. In other words, when the second casing 32 is closed with respect to the first casing 31, the rotating base 42 is at the first position; otherwise, when the second casing 32 is open with respect to the first casing 31, the rotating base 42 is at the second position.

Furthermore, in the present embodiment, the first connecting element 43 has a retaining trough 431 for enhancing the position-limiting function of the first connecting element 43 with respect to the second connecting element 44. The shape of the retaining trough 431 is not limitative. Through matching a part of the second connecting element 44 with the shape of the retaining trough 431, the stability of the second connecting element 44 at the second position can be enhanced when the second connecting element 44 is rotated to abut against the retaining trough 431. In the present embodiment, a part of the second connecting element 44 further fits into the retaining trough 431, which is not in a limiting sense.

It is noteworthy that, referring to FIG. 4A and FIG. 4C, the rotating base 42 has a supporting surface 421. The angle θ between the normal line D1 of the supporting surface 421 at the first position and the normal line D2 of the supporting surface 421 at the second position may be between 80 degrees and 100 degrees. In the present embodiment, the angle θ between the normal line D1 and the normal line D2 is 90 degrees for example without in a limiting sense.

Therefore, since the hinge structure 4 of the present embodiment uses the two ends of the first connecting element 43 and the second connecting element 44 to pivotally connected to the base 41 and the rotating base 42, respectively, to form a structure that the rotating base 42 can be rotated with respect to the base 41, and uses the position-limiting function provided by the second connecting element 44 abutting against the first connecting element 43, the hinge structure 4 of the present embodiment can be assembled without changing the shape and appearance of the first casing 31 and the second casing 32.

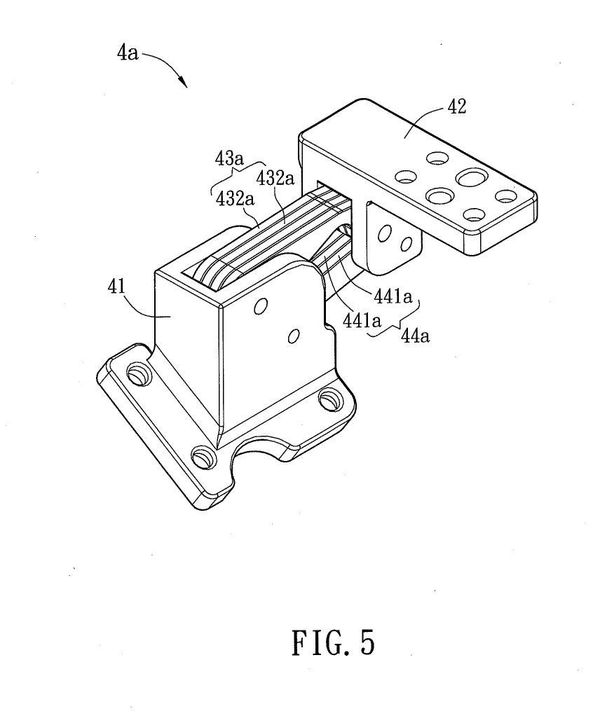

FIG. 5 is a schematic diagram showing another hinge structure 4a according to the preferred embodiment of the invention. Referring to FIG. 5, the first connecting element 43a of the hinge structure 4a may also have a plurality of first sub-connecting elements 432a, and the second connecting element 44a may have a plurality of second sub-connecting elements 441a. The numbers of the first sub-connecting elements 432a and the second sub-connecting elements 441a are not in any limiting sense. By this design, the manufacturing difficulty of the first sub-connecting elements 432a and the second sub-connecting elements 441a may be reduced while the manufacturing precision may be enhanced.

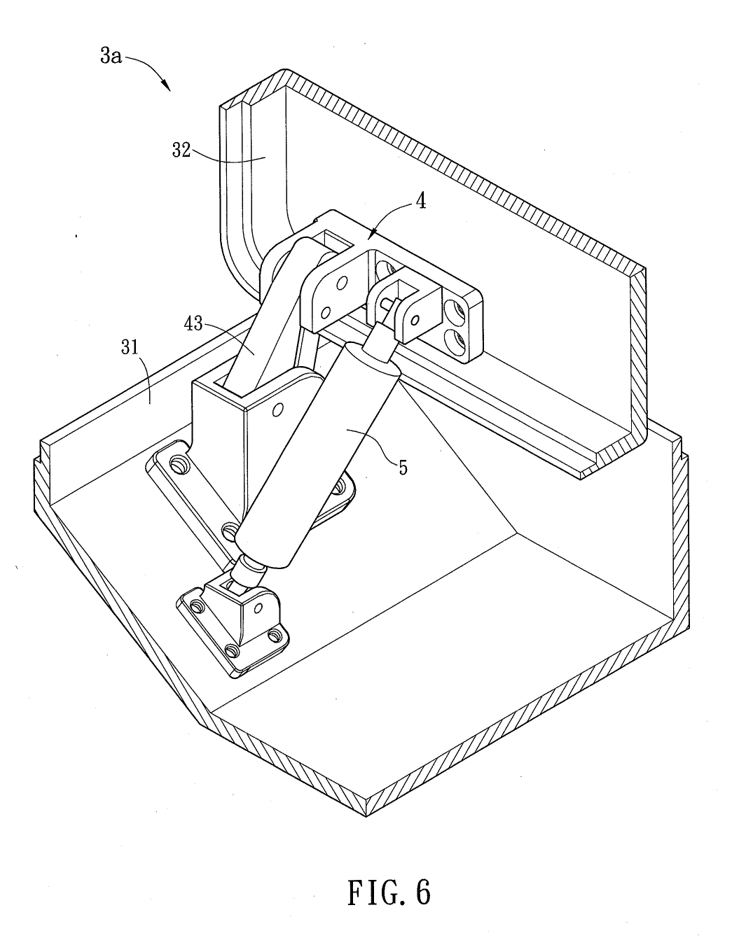

FIG. 6 is a schematic diagram showing another electronic apparatus 3a according to a preferred embodiment of the invention. Referring to FIG. 6, the electronic apparatus 3a may further include an elastic element 5. The elastic element 5 may be, for example, a pneumatic spring or a hydraulic spring, the size of which is not in a limiting sense. The two ends of the elastic element 5 are connected to the first casing 31 and the second casing 32 respectively. Therefore, when the user opens the second casing 32 to a certain angle, the elastic element 5 can reduce the force applied by the user. To the contrary, when the user closes the second casing 32, the elastic element 5 can prevent the injury of the user or the damage of the casing due to the sudden falling of the second casing 32.

To sum up, the electronic apparatus and the hinge structure thereof of the invention uses a first connecting element and a second connecting element to pivotally connect a base to a rotating base. The base is disposed at the first casing of the electronic apparatus, and the rotating base is disposed at the second casing of the electronic apparatus. Since the hinge structure of the present invention forms a structure that the rotating base is capable of rotating with respect to the base, and uses the second connecting element to abut against the first connecting element to realize the position-limiting function, the hinge structure can be assembled without changing the shape and appearance of the first casing or the second casing. Therefore, the aesthetic appearance of the electronic apparatus can be improved and the structure of the casings can be strengthened.

Although the invention has been described with reference to specific embodiments, this description is not meant to be construed in a limiting sense. Various modifications of the disclosed embodiments, as well as alternative embodiments, will be apparent to persons skilled in the art. It is, therefore, contemplated that the appended claims will cover all modifications that fall within the true scope of the invention.

What is claimed is:

1. A hinge structure for pivotally connecting a first casing to a second casing capable of being open and closed with respect to the first casing, comprising:
a base disposed at the first casing;
a rotating base disposed at the second casing;
a first connecting element having a retaining trough, wherein two ends of the first connecting element are pivotally connected to the base and the rotating base, respectively; and
a second connecting element, two ends of which pivotally connected to the base and the rotating base, respectively, the shape of a part of the second connecting element being matched with the retaining trough, and a distance between positions on the rotating base where the first connecting element and the second connecting element are pivotally connected is smaller than a distance between positions on the base where the first connecting element and the second connecting element are pivotally connected,
wherein the rotating base rotates between a first position and a second position with respect to the base through the first connecting element and the second connecting element, when the second casing is closed with respect to the first casing, the rotating base is at the first position, and when the second casing is open with respect to the first casing, the rotating base is at the second position.

2. The hinge structure according to claim 1, wherein when the rotating base is at the second position, a part of the second connecting element is inserted into the retaining trough.

3. The hinge structure according to claim 1, wherein the rotating base has a supporting surface, and an included angle between a normal line of the supporting surface at the first position and the normal line of the supporting surface at the second position ranges from 80 degrees to 100 degrees.

4. The hinge structure according to claim 1, wherein the first connecting element has a plurality of first sub-connecting elements, and the second connecting element has a plurality of second sub-connecting element.

5. An electronic apparatus, comprising:
a first casing;
a second casing capable of being open and closed with respect to the first casing; and
a hinge structure pivotally connecting the first casing to the second casing, the hinge structure comprising:
a base disposed at the first casing;
a rotating base disposed at the second casing;
a first connecting element having a retaining trough, wherein two ends of the first connecting element are pivotally connected to the base and the rotating base, respectively; and
a second connecting element, two ends of which pivotally connected to the base and the rotating base, respectively, the shape of a part of the second connecting element being matched with the retaining trough, and a distance between positions on the rotating base where the first connecting element and the second connecting element are pivotally connected is smaller than a distance between positions on the base where the first connecting element and the second connecting element are pivotally connected,
wherein the rotating base rotates between a first position and a second position with respect to the base through the first connecting element and the second connecting element, when the second casing is closed with respect to the first casing, the rotating base is at the first position, and when the second casing is open with respect to the first casing, the rotating base is at the second position.

6. The electronic apparatus according to claim 5, wherein when the rotating base is at the second position, a part of the second connecting element is inserted into the retaining trough.

7. The electronic apparatus according to claim 5, wherein the rotating base has a supporting surface, and an included angle between a normal line of the supporting surface at the first position and the normal line of the supporting surface at the second position ranges from 80 degrees to 100 degrees.

8. The electronic apparatus according to claim 5, wherein the first connecting element has a plurality of first sub-connecting elements, and the second connecting element has a plurality of second sub-connecting element.

9. The electronic apparatus according to claim 5, further comprising:
an elastic element, two ends of which being connected to the first casing and the second casing, respectively.

10. The electronic apparatus according to claim 5, wherein the electronic apparatus is an all-in-one desktop computer.
